(19) United States
(12) Patent Application Publication
(10) Pub. No.: US 2025/0291014 A1
(43) Pub. Date: Sep. 18, 2025

(54) MAGNETIC RESONANCE IMAGING APPARATUS AND IMAGE PROCESSING METHOD

(71) Applicant: FUJIFILM Corporation, Tokyo (JP)

(72) Inventors: Atsushi KURATANI, Tokyo (JP); Taisei UEDA, Tokyo (JP)

(73) Assignee: FUJIFILM Corporation, Tokyo (JP)

(21) Appl. No.: 19/015,052

(22) Filed: Jan. 9, 2025

(30) Foreign Application Priority Data
Mar. 18, 2024 (JP) 2024-042428

(51) Int. Cl. G01R 33/56; G01R 33/565

(52) U.S. Cl. CPC G01R 33/5608; G01R 33/56509

(57) ABSTRACT

An object is to enable appropriate movement correction while minimizing an SN ratio deterioration caused by movement correction.

A computing unit that performs movement correction estimates an SN ratio of an image before the movement correction and an SN ratio of an image after the movement correction, determines deterioration of the SN ratio caused by the movement correction, and selects an appropriate correction process according to the determination. In addition, in order to appropriately perform such a movement correction process, a user interface that displays a parameter related to the movement correction and that accepts a user designation is provided.

### CROSS-REFERENCE TO RELATED APPLICATIONS

The present application claims priority under 35 U.S.C. § 119 to Japanese Patent Application No. 2024-042428, filed Mar. 18, 2024. Each of the above application(s) is hereby expressly incorporated by reference, in its entirety, into the present application.

### BACKGROUND OF THE INVENTION

### 1. Field of the Invention

The present invention relates to a magnetic resonance imaging apparatus (hereinafter, referred to as an MRI apparatus) and a method of processing measurement data collected by the MRI apparatus, and more particularly, to an image processing method involving movement correction for reducing an effect of a movement.

### 2. Description of the Related Art

In imaging with an MRI apparatus, movements of an examination target (subject) during imaging cause artifacts and lead to a degradation in image quality. The movements include not only periodic movements of the subject such as respiratory motion and cardiac motion but also sudden movements of the subject and the like, and various techniques have been proposed to reduce movement artifacts according to a type of movement.

As a movement correction technique in the related art, a technique has been proposed in which movement information obtained from a movement detection device such as a camera installed separately from an MRI apparatus, or movement information detected from measurement data or a nuclear magnetic resonance signal for movement detection, which is referred to as a navigator or a navigator echo, in the MRI apparatus is used to specify data collected in a case in which movement is detected (hereinafter, referred to as movement-affected data), in measurement data for subject image generation, and the movement-affected data is removed or corrected to reconstruct an image (JP2023-22669A).

Various methods are known for processing the movement-affected data, and examples thereof include a method of removing the movement-affected data from the measurement data and generating an image by applying an image reconstruction method through compressed sensing or parallel imaging using the remaining measurement data after the removal, and a method of correcting the movement-affected data using, in a case in which there is data that is not affected by the movement around the movement-affected data (data to be removed), the surrounding data or using reference data acquired separately and the like (JP2020-130867A).

In addition, JP2015-536746A describes that, for non-rigid motion such as movement of eyeballs or skin among movements, a moving portion is detected from measurement data, data of the moving portion is removed, and a remaining portion of the measurement data that is not removed and an image reconstructed from the measurement data before removal are used to reconstruct a movement-corrected image.

### SUMMARY OF THE INVENTION

In a case in which an image is reconstructed by removing the movement-affected data, there is a problem of a decreased signal-to-noise ratio (hereinafter, abbreviated as an SN ratio or an SNR). The deterioration of the SN ratio differs depending on a configuration of a receive coil, an amount of data to be removed, and the like, but the SN ratio deterioration after movement correction has not been sufficiently studied in the related art. For example, JP2023-22669A discloses a method of varying a reconstruction method or determining the necessity for re-measurement according to a type of movement (such as periodic movements or sudden movements), but does not describe a movement correction method that takes into consideration the deterioration of the SN ratio after movement correction.

JP2015-536746A proposes that an image is reconstructed using an image that includes movement artifacts but has a high SN ratio (that is, an image reconstructed from measurement data before removing data with movements) and data after removing the data with movements to reduce movement artifacts while maintaining a high SN ratio, but this technique assumes a specific localized movement, such as non-rigid motion and is not suitable for correcting rigid motion, such as sudden movements of the subject.

Moreover, it is desirable for the movement correction to respond flexibly depending on a situation of imaging and a type of movement occurring, but the related art does not provide means for flexibly suppressing the SN ratio deterioration in accordance with the situation of imaging and the like.

An object of the present invention is to provide a technique that enables appropriate movement correction while minimizing SN ratio deterioration caused by movement correction. In addition, another object of the present invention is to provide a technique capable of flexibly responding to SN ratio deterioration in accordance with a situation.

According to the present invention, in an MRI apparatus, a computing unit that performs movement correction estimates an SN ratio of an image before the movement correction and an SN ratio of an image after the movement correction, determines deterioration of the SN ratio caused by the movement correction, and selects an appropriate correction process according to the determination. Additionally, in order to appropriately perform such a movement correction process, a user interface that displays a parameter related to the movement correction and that accepts a user designation is provided.

That is, according to the present invention, there is provided an MRI apparatus comprising: an imaging unit that measures a nuclear magnetic resonance signal generated from a subject and that collects measurement data for generating an image of the subject; a computing unit that performs a computational operation using the measurement data; and a control unit that controls the imaging unit and the computing unit. The computing unit includes a movement-affected data specifying unit that specifies, as movement-affected data, a nuclear magnetic resonance signal collected in a case in which a movement of the subject is detected in the measurement data, an SNR comparing unit that compares a signal-to-noise ratio of a first image generated from first measurement data before the movement-affected data is removed with a signal-to-noise ratio of a second image generated from second measurement data after the movement-affected data is excluded, and an image generation unit that selects a correction process to be applied to at least one of the second measurement data or the second image according to a comparison result of the SNR comparing unit and that performs the selected correction process to generate the image of the subject.

In addition, according to the present invention, there is provided an image processing method of processing measurement data consisting of a nuclear magnetic resonance signal collected by an MRI apparatus to generate an image of a subject, the image processing method comprising the following steps.

The steps include: a step of specifying, as movement-affected data, a nuclear magnetic resonance signal collected in a case in which a movement of the subject is detected; a step of comparing a signal-to-noise ratio of a first image generated from measurement data before the movement-affected data is removed with a signal-to-noise ratio of a second image generated from measurement data after the movement-affected data is excluded, in the measurement data; a step of selecting, from among a plurality of movement correction processes, a correction process to be applied to at least one of the measurement data after the movement-affected data is excluded or the second image according to a comparison result; and a step of performing the selected correction process to generate the image of the subject.

According to the present invention, by selecting and applying the movement correction process to be performed on the measurement data based on the comparison of the SN ratios of the images reconstructed from the measurement data before and after removing the movement-affected data, it is possible to suppress an SN ratio loss and to obtain an appropriately movement-corrected image.

### BRIEF DESCRIPTION OF THE DRAWINGS

FIG. 1 is a diagram showing an outline of an MRI apparatus to which the present invention is applied.

FIG. 2 is a functional block diagram of a computing unit of Embodiment 1.

FIG. 3 is a flowchart showing processing of the computing unit.

FIGS. 4A and 4B are diagrams showing an example of a navigator sequence.

FIG. 5 is a diagram showing an example of movement information.

FIG. 6 is a diagram showing an example of exclusion data.

FIG. 7 is a diagram illustrating application of filters having different intensities.

FIG. 8 is a flowchart showing processing of Embodiment 2.

FIG. 9 is a diagram illustrating the processing of Embodiment 2.

FIG. 10 is a diagram showing an example of a GUI of Embodiment 3.

### DESCRIPTION OF THE PREFERRED EMBODIMENTS

Hereinafter, an outline of an MRI apparatus to which the present invention is applied will be described.

MRI apparatuses are known in various types, such as a horizontal magnetic field type and a vertical magnetic field type, depending on a direction of a generated static magnetic field, as well as a permanent magnet type, a constant current electromagnet type, and a superconducting magnet type, depending on a magnet for generating the static magnetic field. The present invention can be applied to the known MRI apparatuses. Additionally, a shape of a static magnetic field space in which a subject is placed also varies, such as a cylindrical shape and a planar shape sandwiched between upper and lower magnets, and the present invention can be applied to any of these shapes.

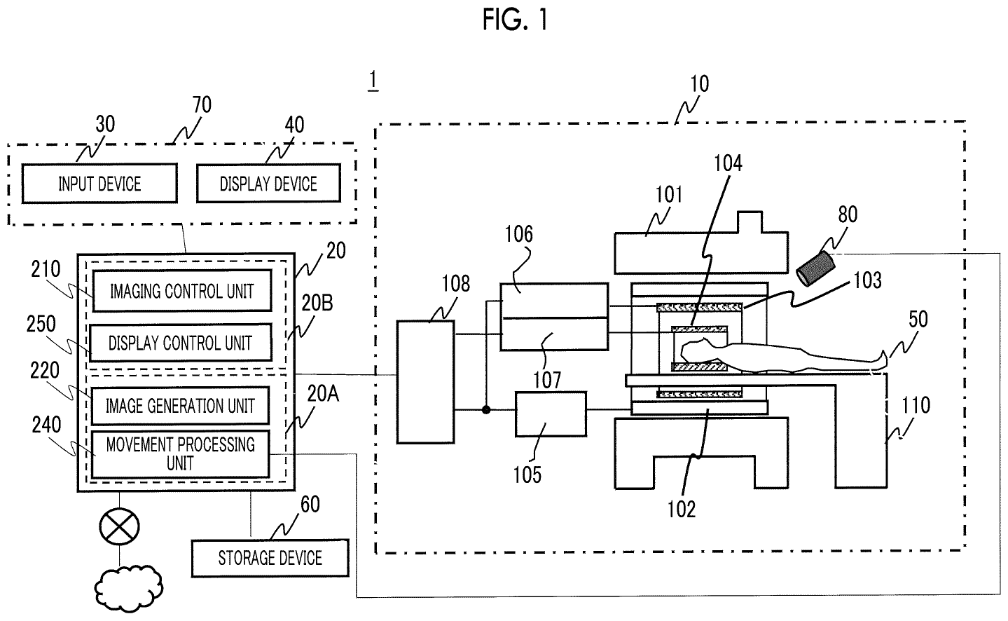

First, the outline of the MRI apparatus to which the present invention is applied will be described with reference to FIG. 1.

As shown in FIG. 1, an MRI apparatus 1 comprises a static magnetic field generation device (static magnetic field generating magnet) 101 that generates a static magnetic field, an RF transmission unit 106 that applies a high-frequency magnetic field pulse to a subject 50 placed in a space in which the static magnetic field is generated by the static magnetic field generating magnet, an RF reception unit 107 that receives a nuclear magnetic resonance signal emitted by the subject 50, a gradient magnetic field coil 102 that generates a gradient magnetic field pulse for applying a magnetic field gradient to the static magnetic field, a gradient magnetic field power supply 105 (collectively referred to as a gradient magnetic field generation unit), a sequencer 108 that controls the gradient magnetic field power supply 105, the RF transmission unit 106, and the RF reception unit 107 in accordance with a predetermined pulse sequence, and a processor 20 that controls the entire apparatus including the sequencer 108. An RF transmission coil 103 for applying an RF pulse generated by the RF transmission unit 106 to the subject and an RF receive coil 104 for detecting the nuclear magnetic resonance signal generated by the subject 50 are disposed in proximity to the subject 50. Hereinafter, the RF transmission unit 106, the RF reception unit 107, the gradient magnetic field generation unit, and the like will also be collectively referred to as an imaging unit 10.

The processor 20 consists of one or a plurality of processors, can be configured as a general-purpose computer provided with a memory and a CPU, and functions as a computing unit 20A and a control unit 20B. For example, as a function of the computing unit 20A, as shown in the functional block diagram of FIG. 1, an image generation unit 220 that generates an image of the subject 50 using the nuclear magnetic resonance signal received by the RF reception unit 107, and a movement processing unit 240 that processes a signal from detection means for detecting a movement of an examination target during examination, acquires a magnitude and a duration (movement information) of the movement, and performs a computational operation or control for removing an effect of the movement using the movement information are provided. In addition, the control unit 20B has a function of controlling the operation of the entire apparatus and can comprise an imaging control unit 210 that controls the operation of the imaging unit 10, a display control unit 250 for displaying the image generated by the image generation unit 220, and the like. The functions of the processor 20 are implemented by the CPU uploading a predetermined program. Additionally, some of the functions can also be implemented using a programmable IC.

In addition, the function related to the computing unit in the processor 20 can also be implemented by an image processing device independent of the MRI apparatus 1.

An input device 30 for an operator to input a command, data, and the like necessary for imaging, a display device 40 that displays the image generated by the image generation unit 220 and the like, a storage device 60, and the like are connected to the processor 20. The storage device 60 includes an internal storage device and an external storage device, and the external storage device may be a storage device such as a cloud connected through the Internet or the like. Additionally, the MRI apparatus 1 can also exchange data with an external database (not shown) such as PACS. The input device 30 and the display device 40 are installed in proximity to each other and function as a user interface (UI unit 70).

In addition, the MRI apparatus 1 may be provided with optical detection means such as a surveillance camera 80 for monitoring a state of the subject 50 disposed in the static magnetic field space, and it is also possible to detect the movement of the subject 50 using a video from the surveillance camera 80. In that case, the movement processing unit 240 receives information from the surveillance camera 80 and performs predetermined processing such as movement correction on measurement data acquired by the imaging unit 10.

Since the configuration and the flow of imaging of the imaging unit 10 are the same as those of the imaging unit in the related art, the description thereof will be omitted, and hereinafter, the embodiment of the present invention will be described with a focus on the movement processing unit 240.

### Embodiment 1

The MRI apparatus of the present embodiment estimates, in a case in which image reconstruction is performed by specifying movement-affected data and then removing the movement-affected data in movement processing, a degree of SN ratio deterioration, that is, an SN ratio loss, as compared with a case in which image reconstruction is performed without removing the movement-affected data, and selects subsequent processing according to the degree of the SN ratio loss. The subsequent processing includes a correction process using a filter, a half estimation process, and the like, and a filtering process includes filtering processes with different intensities.

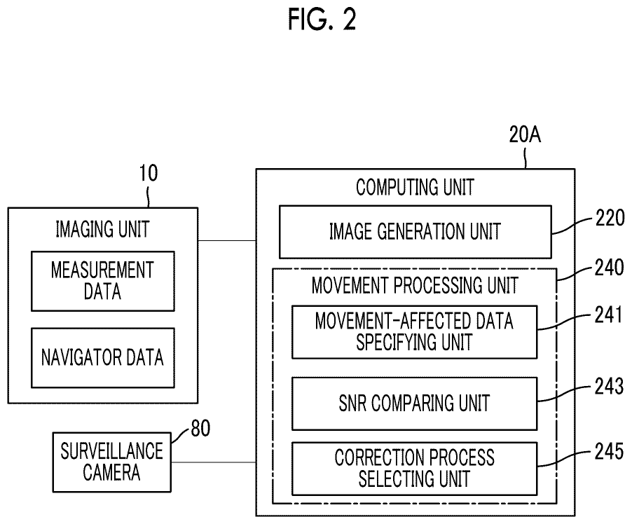

FIG. 2 shows a functional block diagram of the computing unit 20A that executes the above-described functions. As shown in FIG. 2 the computing unit 20A includes a movement-affected data specifying unit 241, an SNR comparing unit 243, and a correction process selecting unit 245, in addition to the image generation unit 220. As shown in FIG. 2, these may be functions included in the movement processing unit 240, or each can be configured as an independent processor.

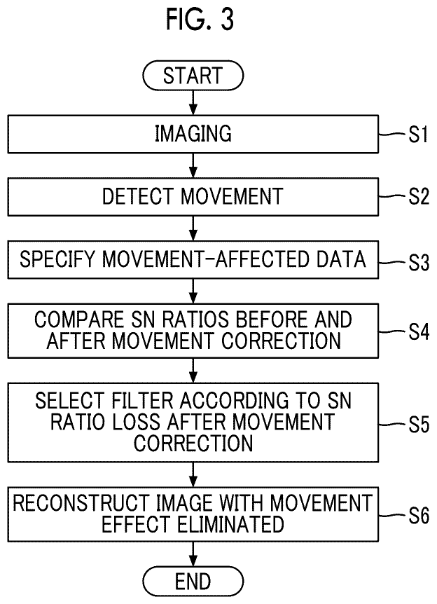

Hereinafter, an operation of the MRI apparatus of the present embodiment that includes the movement processing will be described with reference to the flowchart of FIG. 3.

### Imaging: S1

First, the imaging unit 10 performs imaging under the control of the imaging control unit 210 (S1). Imaging is performed under the control of the sequencer 108 based on an imaging pulse sequence registered in advance or set by the user via the UI unit 70, and imaging parameters such as TE, TR, FOV, and an acceleration rate (R-factor). Imaging is performed to collect measurement data for generating the image of the subject 50, that is, k-space data.

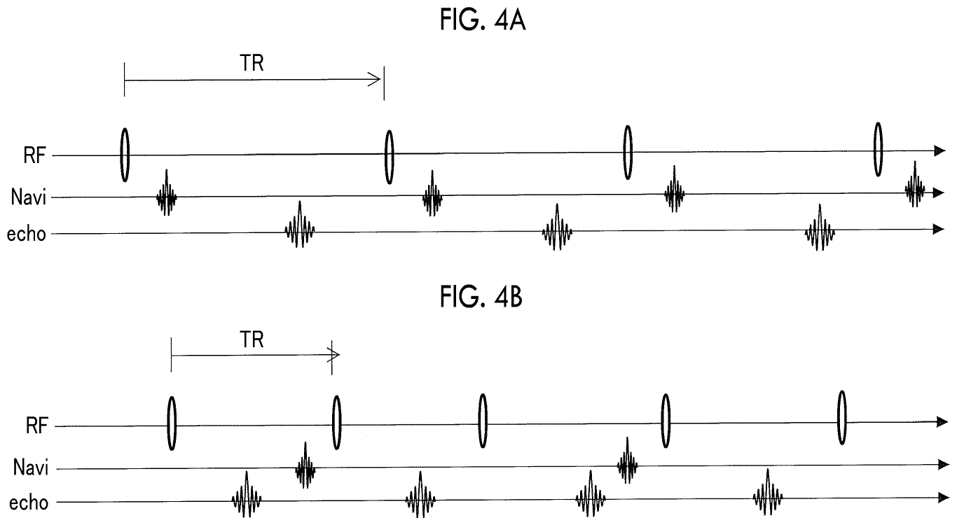

The pulse sequence may include a navigator sequence for detecting the movement of the subject 50, and in this case, navigator echo data (navigator data) is also collected. The navigator echo is a nuclear magnetic resonance signal collected from a predetermined region without applying phase encoding, separately from a nuclear magnetic resonance signal (referred to as a main imaging echo) for generating the image of the subject 50. Since the navigator sequence for acquiring the navigator echo and a method of acquiring the movement information from the navigator data are established by known sequences or methods, the detailed description thereof will be omitted in the present specification, but an example thereof is shown in FIGS. 4A and 4B. FIGS. 4A and 4B show examples of acquiring the main imaging echo and the navigator echo within the same repetition time (TR) after the RF pulse is applied, and FIG. 4A shows an example of acquiring the navigator echo before the main imaging echo, and FIG. 4B shows an example of acquiring the navigator echo after the main imaging echo. In addition, a navigator sequence for collecting only a navigator echo may be added separately from the pulse sequence for collecting the main imaging echo.

Additionally, in a case in which the MRI apparatus 1 is provided with the movement detection device such as the surveillance camera 80 for movement detection, a signal or a video from the movement detection device is transmitted to the movement processing unit 240 in parallel with the imaging. As the movement detection device, in addition to the surveillance camera 80, various devices are known such as an infrared sensor and a balloon worn by the subject 50, and any of these devices can be used alone or in combination. Further, since it may be difficult to execute the navigator sequence depending on the imaging purpose or the imaging sequence, a configuration can be employed in which the user appropriately selects the sequence.

### Analysis of Movement Information: S2 and Specification of Movement-Affected Data: S3

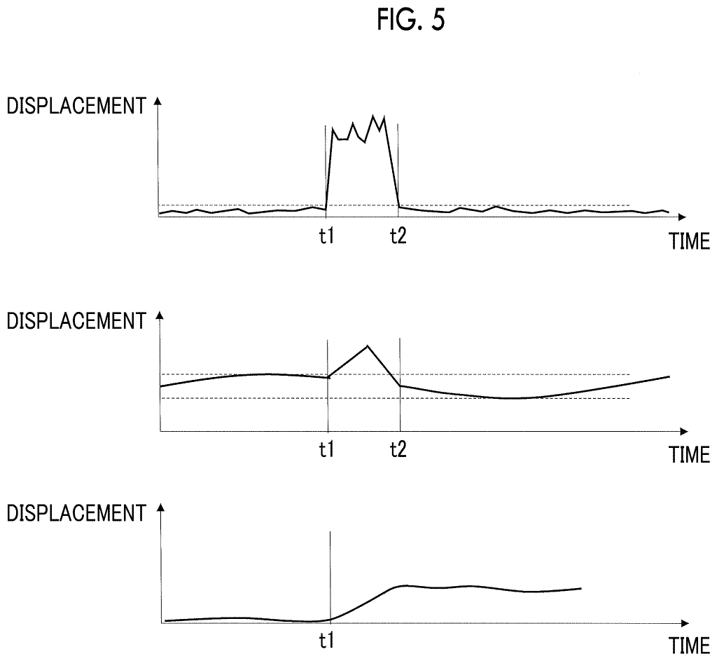

Upon starting the imaging, the computing unit (movement processing unit 240) analyzes the navigator echo or the video from the surveillance camera 80 (S2) and specifies data (movement-affected data) collected in a case in which the movement is detected, in the measurement data (S3). Although the movement information obtained by the movement detection means differs, the movement information is obtained as a displacement or variation (change) of the subject along the time axis. FIG. 5 shows an example of the movement information obtained from the navigator echo or the surveillance camera 80. The example shown in FIG. 5 is information (graph) indicating the displacement of a predetermined part of the subject 50 along the time axis, and by analyzing this graph, the magnitude of the displacement (an absolute value or a relative value), the time at which a displacement of a predetermined magnitude occurs, the period of the displacement, and the like can be obtained.

In order to specify the movement-affected data, the movement processing unit 240 (movement-affected data specifying unit 241) can set threshold values for the magnitude, duration, frequency, and the like of the movement, and these threshold values can be used to specify the movement that affects the data and to specify the measurement data collected during the time when the movement occurs.

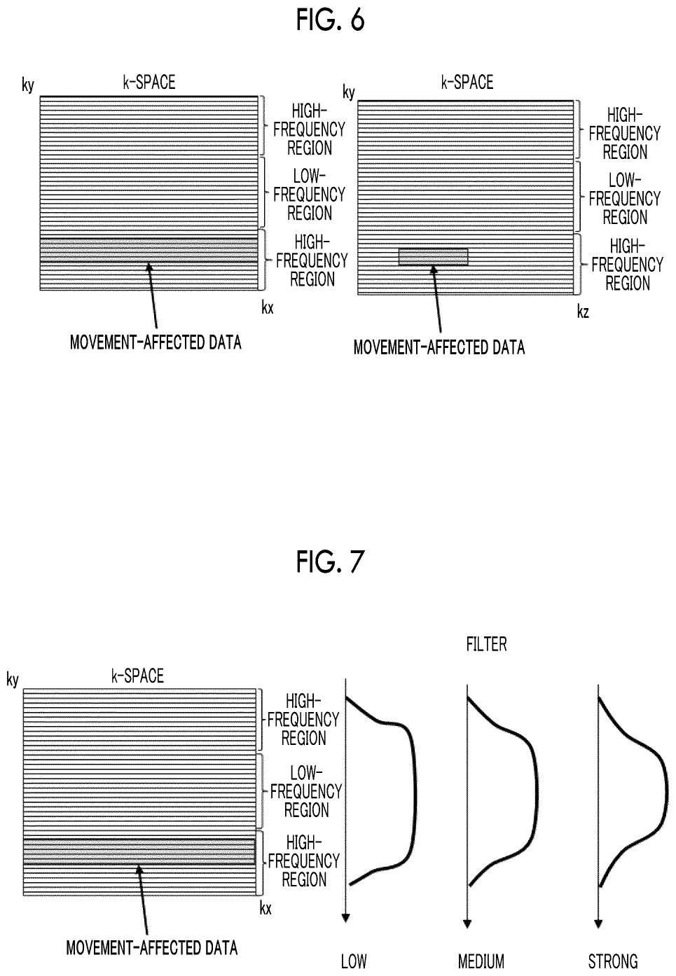

FIG. 6 shows an example of the specified movement-affected data. A left side of FIG. 6 shows k-space data (kx-ky space) in a case of 2D imaging, and a right side thereof shows k-space data (ky-kz space) in a case of 3D imaging. Although it differs depending a k-space data collection method (sampling order), in a case of 2D imaging, a ky direction is a phase encoding direction and typically corresponds to the time axis, and kx-ky line data is specified as the movement-affected data. In the 3D imaging, in a case in which echoes are collected while changing the phase encoding within a single slice encoding, some of ky-kz line data may be specified as the movement-affected data.

### Estimation of SN Ratios of Images Before and After Movement Correction: S4

The SNR comparing unit 243 calculates, in a case in which the specified movement-affected data is removed from the measurement data, a loss of the SN ratio of the image reconstructed from the measurement data after the removal.

In the movement correction, for example, after the movement-affected data is removed, in a case in which the movement-affected data is not low-frequency region data and sufficient k-space data for reconstruction remains even after the movement-affected data is removed, the removed data portion is zero-filled to perform image reconstruction. However, the image reconstructed in this manner results in a deterioration of the SN ratio due to a decrease in the number of pieces of data. The SNR comparing unit 243 calculates the SN ratio loss by comparing an SN ratio of an image reconstructed by removing the movement effect with an SN ratio of an image reconstructed using measurement data (k-space data) in a case in which there is no movement effect, that is, in a case in which the movement-affected data is not removed.

In general, in a case in which an SN ratio (SNR) of an image obtained through full sampling is denoted as SNR-0, the SN ratio of an image can be represented by the following equation using a g-factor of the receive coil used for imaging and an R-factor (acceleration rate) during imaging.

SN ratio=SNR-0/(g-factor*√(R-factor))

Here, the SNR-0 and the g-factor are used in common to the image before the movement-affected data is removed and the image after the removal, and the difference in the SN ratio between the two images arises due to the change in the R-factor resulting from the exclusion of data. That is, by removing the movement-affected data, a thinning-out rate of the k-space (the proportion of the number of pieces of unmeasured data to the number of pieces of full-sampled data: the reciprocal of the R-factor) is a value obtained by adding the number of pieces of movement-affected data to be removed to the denominator.

Therefore, by using the thinning-out rates before and after the exclusion of the movement-affected data, the loss of the SN ratio in the image after the exclusion (the proportion of the SN ratio deterioration in a case in which the SN ratio before the exclusion is set to 100) can be estimated by the following equation.

SN ratio loss={1/g(R1)*√(1/R1)−1/g(R2)*√(1/R2)}g(R1)/√(1/R1)

In the equation, R1 is an R-factor before the exclusion of the movement-affected data, R2 is a reciprocal of the thinning-out rate after the exclusion of the movement-affected data (corresponding to the R-factor), and g( ) is a function of the g-factor that is dependent on the R-factor.

Here, the SN ratio loss is calculated using the thinning-out rate in a simple manner, but it is also possible to calculate the SN ratio loss by using a known SN ratio estimation technique to perform the SN ratio estimation for each of the image in which there is no effect of the movement and the image after the movement-affected data is removed. However, since this method does not perform the estimation process using the image itself, there is no computational load, and easy estimation and selection of the next filtering process are possible.

### Selection of Movement Correction Process: S5

In the present embodiment, the movement correction process is implemented by removing the movement-affected data and filtering, and the intensity of the filter is varied based on the comparison result of the SN ratio. The filtering process may be processing either in an image space or in the k-space. In a case of a filter in the image space, for example, a smoothing filter such as a Gaussian filter, a bilateral filter, or a median filter can be used. As the k-space filter (frequency domain filter), a low-pass filter (LPF), a Fermi filter, or the like can be used. In some cases, a high pass filter (HPF) or a band pass filter (BPF) can be combined with these filters. The k-space filter is a process of multiplying the k-space data by a predetermined window function, and as the window function, one or a combination of Hanning, Hamming, Gaussian, Kaiser-Blackman, Fermi, and the like can be used.

Regarding the types and combination of the filters, a filter configuration may be employed to suppress truncation artifacts (also referred to as ringing artifacts) that occur due to data truncation. As the filter that suppresses the truncation artifacts, for example, in addition to a smoothing filter used in the image space, a technique of combining an HPF and the like with an LPF and a BPF as the basis for k-space filters is known, and these can be applied.

The selection of the intensity of the filter is based on the SN ratio loss calculated in S4 described above. For example, two or more threshold values are set, and then the intensity is set to “low” in a case in which the SN ratio loss is at the lower threshold value (for example, 20% or less), the intensity is set to “high” in a case in which the SN ratio loss is at the higher threshold value (40% or greater), and the intensity is set to “medium” in a case in which the SN ratio loss falls between 20% and 40%. In either case, the intensity of the filter is changed for high-frequency region data.

FIG. 7 conceptually shows the k-space filter. In FIG. 7, the left side shows 2D k-space data, where data specified as the movement-affected data is located on a high-frequency region side. In this example, three types of filters having different intensities are prepared, and the filter is applied more strongly in the high-frequency region as the intensity increases from “low” to “high”. By processing the measurement data after the movement-affected data is removed using such filters, the SN ratio loss is restored, and the measurement data is smoothed with an intensity corresponding to the magnitude of the SN ratio loss. By reconstructing the measurement data, an image with no SN ratio deterioration and with the effect of the movement eliminated can be obtained.

In the above description, a case has been described in which the correction process selecting unit 245 automatically selects the intensity of the filter using the threshold value set in advance, but it is also possible to accept the selection by the user via the UI unit 70. Additionally, regarding the types of filters and the application methods, a configuration may be employed in which criteria based on the number of pieces of the movement-affected data, the disposition on the k-space, and the like are provided and the types of filters and the application methods are selected in accordance with the criteria.

### Image Reconstruction: S6

In a case of using, for example, the k-space filter, the image generation unit 220 performs, after zero-filling the measurement data after the movement-affected data is removed with the filter intensity selected by the correction process selecting unit 245, a filtering process on the measurement data to perform image reconstruction. The reconstruction method is not particularly limited, and for example, a known method such as image reconstruction based on a PI method using a reception sensitivity distribution of a receive coil consisting of a plurality of small coils or image reconstruction through repeated computational operations such as compressed sensing can be used. In addition, it is also possible to perform the filter correction process and the image reconstruction within a single reconstruction method.

As described above, in the MRI apparatus of the present embodiment, the computing unit has a movement correction function, and the movement correction is performed using a method of suppressing the deterioration of the SN ratio. Therefore, the SN ratios of the images before and after the movement correction are estimated, the deterioration (SN ratio loss) of the SN ratio caused by the movement correction is determined, and the correction process method is selected. As a result, it is possible to obtain a reconstructed image that does not include the movement-affected data and that has no deterioration of the SN ratio.

In Embodiment 1, a case has been described in which a relatively small amount of movement-affected data is excluded from the measurement data, and image reconstruction involving the correction process on the measurement data after the exclusion is performed; However, in a case in which a large amount of movement-affected data is excluded, in a case in which the movement-affected data is concentrated in a low-frequency region of the k-space, and the like, re-measurement of that data or the entire k-space data may be performed instead of performing the correction process.

### Embodiment 2

In Embodiment 1, the movement processing unit 240 selects the intensity of the filtering process to be performed as the movement correction based on the comparison of the SN ratios of the images before and after the movement correction; however, in the present embodiment, the correction process and an image reconstruction process are further selected according to the position of the movement-affected data on the k-space.

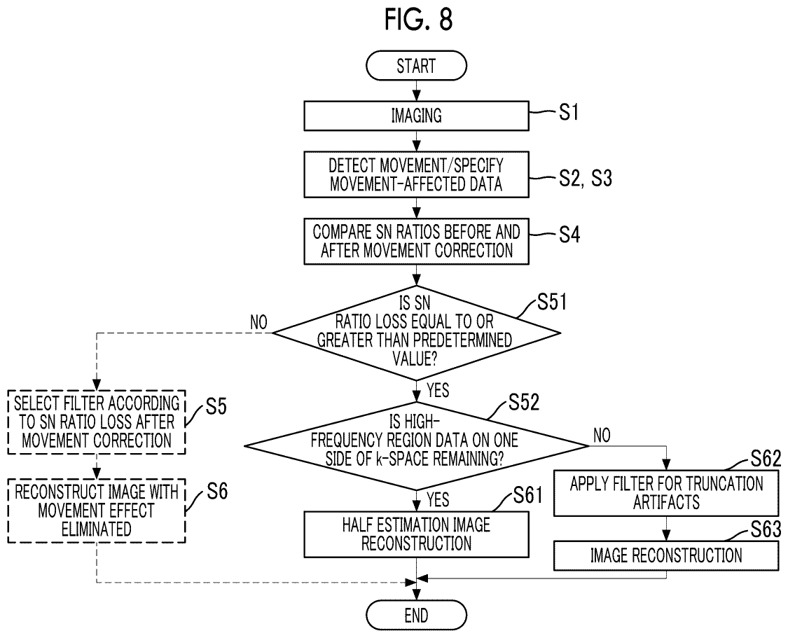

The configuration of the movement processing unit 240 of the present embodiment is the same as the configuration of the movement processing unit 240 of Embodiment 1 shown in FIG. 2, and hereinafter, a flow of processing of the movement processing unit 240 of the present embodiment will be described with reference to the flowchart shown in FIG. 8. In FIG. 8, processing having the same contents as the processing shown in FIG. 3 is indicated by the same reference numerals, and detailed description of the processing will be omitted.

First, while performing imaging (S1), the presence or absence of the movement of the subject is detected using the movement of at least one of the surveillance camera or the navigator data (S2), and in a case in which the movement occurs, for example, in a case in which there is a change in the movement position equal to or greater than a predetermined threshold value, the k-space data collected during that period is specified as the movement-affected data (S3).

Next, the SN ratio of the image in a case in which reconstruction is performed using the k-space data obtained by removing the movement-affected data and zero-filling the data of the removed portion is compared with the SN ratio of the image in a case in which reconstruction is performed on the assumption that there is no movement, thereby calculating the degree of the SN ratio loss (S4). A method of calculating the SN ratio loss in this case is the same as that in Embodiment 1, and the SN ratio loss is calculated based on the thinning-out rate of the k-space data in which the movement-affected data is excluded.

Next, in a case in which the number of pieces of the movement-affected data is relatively large and the SN ratio loss is large, the position of the movement-affected data on the k-space is determined, and the correction process or the reconstruction process after the movement-affected data is removed is decided on (S51, S52).

Specifically, for example, in a case in which the SN ratio loss is 30% or greater, or in a case in which the movement-affected data is a predetermined proportion or more of the k-space data (S51), it is determined whether the movement-affected data is high-frequency region data of the k-space and the high-frequency region data on the opposite side does not include the movement-affected data (S52).

In a case in which the movement-affected data is high-frequency region data of the k-space and there is high-frequency region data symmetrically present, image reconstruction is performed by performing half estimation using the properties of the k-space. That is, processing of inverting only the phase is performed on the high-frequency region data having different phase encoding polarity from that of the movement-affected data to be removed, and the high-frequency region data is substituted for the movement-affected data.

On the other hand, in a case in which there is no complementary high-frequency region data, that is, in a case in which the movement-affected data is also present in a high-frequency region complementary to the high-frequency region in which the movement-affected data is included, correction using a filter is performed instead of half estimation. In this case, similarly to a case in which the SN ratio loss is at or above the higher threshold value (for example, 40%) in Embodiment 1, the filter intensity may be simply increased, but in the present embodiment, a filter for truncation artifacts is used as the filter. For example, the filter is switched from a filter set by default to the filter for truncation artifacts. Here, a state in which the high-frequency region data is thinned out is similar to a situation in which truncation artifacts occur due to data truncation, and by using the filter for truncation artifacts as the filter, it is possible to effectively suppress the occurrence of artifacts caused by the removal of the high-frequency region data.

In a case in which the SN ratio loss is equal to or less than a predetermined threshold value in S51, the intensity of the filter may be selected according to the degree of the SN ratio loss as in Embodiment 1 (S5, S6). In addition, in step S52 of determining the position of the movement-affected data on the k-space, in a case in which the movement-affected data is present in the low-frequency region instead of the high-frequency region, re-measurement is performed in the same manner as in Embodiment 1.

In the flowchart of FIG. 8, it is assumed that the loss of the SN ratio is estimated (FIG. 8: S4, S51); however, in a case in which the SN ratio loss is not calculated and the proportion of the movement-affected data in the high-frequency region of the k-space is equal to or greater than a predetermined proportion, processing in S52 (a process of determining whether there is complementary high-frequency region data in the k-space) may be directly performed to perform half estimation reconstruction or reconstruction after the correction process using the filter for truncation artifacts.

According to the present embodiment, by determining the position of the movement-affected data on the k-space or the presence or absence of the complementary data to select the filter type or to select the image reconstruction, an image with no deterioration in image quality can be obtained while suppressing the SN ratio loss.

### Modification Example 1 of Embodiment 2

In Embodiment 2, in a case in which a relatively large amount of (for example, 30% or more of) high-frequency region data needs to be removed as the movement-affected data, the filter for truncation artifacts is used or the half estimation is performed; however, it is also possible to employ filter selection or image reconstruction using a machine learning model such as a deep convolutional neural network (DCNN).

As the learning model (CNN) that is available for use with the measurement data after the movement effect is removed, for example, by using, as training data, a set of a large number of images obtained by reconstructing k-space data in which high-frequency region data has been randomly removed at a predetermined proportion and an image obtained by reconstructing full-sampled k-space data, a model that is trained to output a full-sampled image in response to an input of an image of the measurement data with missing high-frequency region, a model that is trained to output the measurement data in which the missing data is interpolated in response to an input of the measurement data with missing data in the high-frequency region, or the like can be used.

Additionally, for the filter selection, by performing training using a set of an image reconstructed after processing k-space data, in which high-frequency region data has been randomly removed at a predetermined proportion, by using various filters or a combination of filters and an image obtained by reconstructing the full-sampled k-space data, a model that is trained to output an optimal filter or measurement data processed with that filter in response to an input of the measurement data with missing data in the high-frequency region, or the like can be used.

In the application of the CNN, a CNN having a noise reduction function and the like are also known, and these known CNNs may be combined.

According to the present modification example, it is necessary to separately construct the CNN, but it is possible to select the optimal filter that suppresses the SN ratio loss or to perform image reconstruction even in a case in which a large amount of movement-affected data is included in the high-frequency region data, and it is possible to easily reconstruct the image with a reduced SN ratio loss.

### Modification Example 2 of Embodiment 2

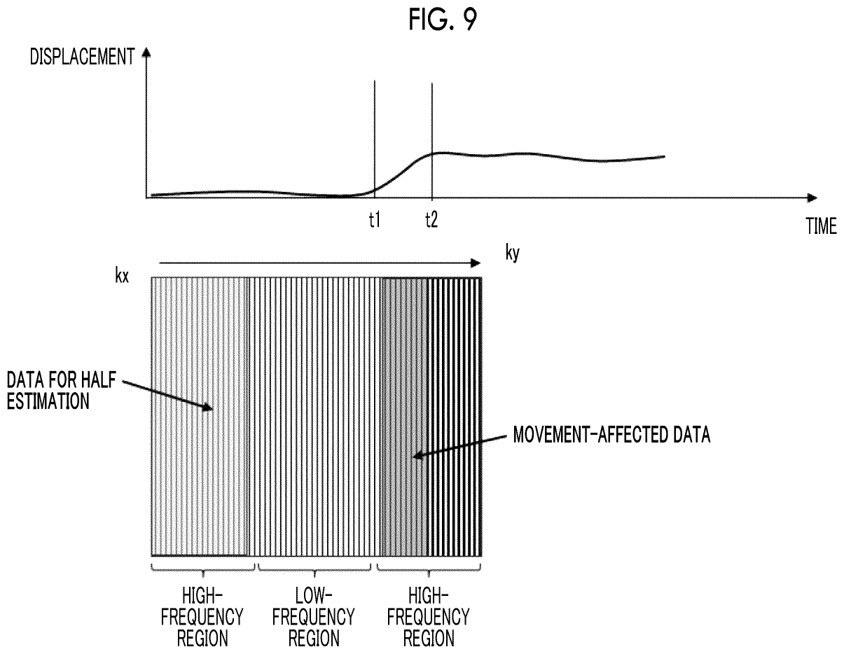

In Embodiment 2, as an example, a case has been described in which some of the high-frequency region data of the k-space is specified and removed as the movement-affected data; however, for example, in the detection of the movement, in a case in which the presence or absence of the movement is determined using a variation amount instead of an absolute value of the displacement of the subject, as shown in FIG. 9, in a case in which it is determined that the movement has occurred from time t1 to t2, the k-space data collected from time t1 to t2 is specified as the movement-affected data. However, in a case in which the subject position is shifted from the original position thereafter, it is necessary to remove the data as the movement-affected data even in a case in which there is no movement.

For such data, phase correction can be used to address this, but in the present modification example, data collected after the subject position has changed, following the collection of the movement-affected data, is also specified as the movement-affected data, and the subsequent correction process is performed in accordance with the flowchart of FIG. 8. That is, in this case as well, the loss of the SN ratios of the images before and after the movement correction is estimated (S4, S51), and the subsequent reconstruction process is decided on in consideration of the data remaining in the high-frequency region of the k-space data (S52).

According to the present modification example, even in a case in which the movement-affected data to be specified differs due to the difference in the movement detection means, it is possible to reliably exclude the data that affects the image.

### Embodiment 3

The present embodiment is an embodiment related to the UI unit 70 of the MRI apparatus 1 and can be applied in common to the embodiments mentioned above.

In Embodiment 1 and Embodiment 2, a case has been described in which the movement processing unit 240 uses the threshold values to automatically select the intensity of the filter, or select whether to perform half estimation or apply the filter for truncation artifacts; however, in the present embodiment, a GUI for prompting the user to make these selections is displayed on the display device 40 of the UI unit 70, and processing is performed in accordance with the user selection.

As the GUI for selecting parameters or conditions related to the movement correction (collectively referred to as a movement parameter), at least one of the movement detection means, the intensity of the filter used for movement correction, the threshold value in a case of filter selection, the filter type, the selection of the half estimation process, or the like can be set.

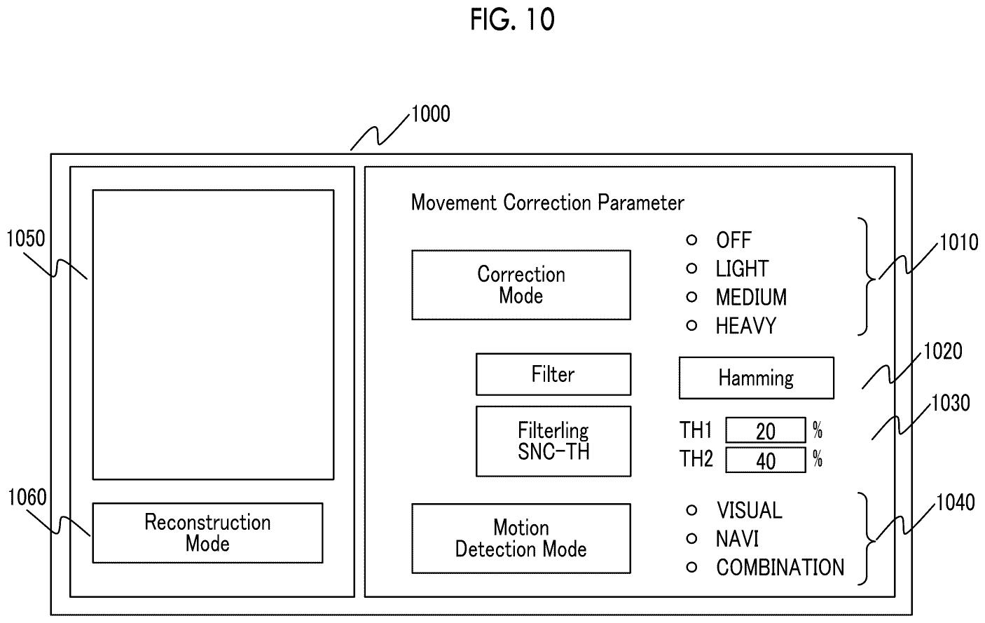

FIG. 10 shows an example of the GUI displayed on the display device 40. FIG. 10 is a screen 1000 for inputting the movement parameter. Such a screen 1000 is displayed, for example, in a case in which the movement correction “required” is selected on a screen for setting imaging conditions such as imaging parameters (TE, TR, FOV, acceleration rate, and the like).

In the example shown in FIG. 10, a block 1010 for selecting the intensity of the movement correction, that is, the intensity of the filter used for movement correction, a block 1020 for selecting the type of filter, a block 1030 for setting the threshold value in a case of determining the filter intensity, a block 1040 for selecting the means for detecting the movement, and a block 1050 for displaying the movement information and the like are set.

As described in Embodiment 1, there are the surveillance camera 80 (“VISUAL”), the navigator data (“NAVI”), and the combination thereof (“COMBINATION”) as the movement detection means, and the user can select any of these via the block 1040. Depending on the imaging purpose or the imaging sequence, it may be difficult to execute the navigator sequence. In addition, there may be a case in which there is a malfunction in the surveillance camera or a case in which the surveillance camera is not provided. The user can set the most appropriate movement detection means in accordance with the imaging purpose or the situation of the system.

In Embodiment 1, the intensity of the filter is set according to the SN ratio loss, but the user can set any intensity via the block 1010. Here, although a GUI is provided to select any of “LIGHT” (weak), “MEDIUM” (medium), or “HEAVY” (strong) as the intensity, a numerical value such as “0 to 3” may be set or selected. Additionally, as shown in FIG. 10, it may also be possible to select the necessity for the filter correction, together with the selection of the intensity. In the selection of the intensity, for example, the result selected by the movement processing unit 240 may be displayed, the user may determine whether the change is necessary, and a user designation may be accepted in a case in which the change is necessary. In this case, a configuration may be employed in which one or a plurality of threshold values (TH1, TH2) used by the movement processing unit 240 are displayed in the block 1030 and the user can change the threshold values. For the filter, a default filter may also be displayed in the block 1020, allowing the user to change the filter.

Further, a configuration may be employed in which a diagram showing the movement-affected data or the movement information detected by the movement detection means together with the movement-affected data in the k-space data, for example, a diagram showing the diagram as shown in FIG. 9, is displayed in the block 1050 or in a separate window. Consequently, the user can make a determination including whether re-measurement should be performed. A button (GUI) 1060 for selecting the half estimation process or the like may be displayed together with the block 1050.

By providing the GUI specialized for the movement processing, the user can flexibly respond to the movement correction and can also acquire the image after the movement correction process with varied filter conditions or the like as post-processing. In this way, a plurality of images with varied conditions can be used as training data for the CNN and can be used to improve the accuracy of the CNN as described in Modification Example 1 of Embodiment 2.

According to the present embodiment, by providing the GUI for setting the movement parameter, it is possible to perform appropriate movement correction tailored to the actual state of imaging, in addition to the automatic processing selection by the system. Moreover, since images with various movement correction conditions can be generated using the measurement data even after imaging, this is effective for evaluating the movement correction process and constructing the CNN.

### EXPLANATION OF REFERENCES

1: MRI apparatus
10: imaging unit
20: processor
20A: computing unit
20B: control unit
30: input device
40: display device
60: storage device
70: UI unit
80: surveillance camera
240: movement processing unit
241: movement-affected data specifying unit
243: SNR comparing unit
245: correction process selecting unit

What is claimed is:

1. A magnetic resonance imaging apparatus comprising:
an imaging unit that measures a nuclear magnetic resonance signal generated from a subject and that collects measurement data for generating an image of the subject; and
one or more processors that performs a computational operation using the measurement data, and controls the imaging unit and the computing unit,
wherein the one or more processors are configured to
specify, as movement-affected data, a nuclear magnetic resonance signal collected in a case in which a movement of the subject is detected in the measurement data,
compare a signal-to-noise ratio of a first image generated from first measurement data before the movement-affected data is removed with a signal-to-noise ratio of a second image generated from second measurement data after the movement-affected data is excluded,
select a correction process to be applied to at least one of the second measurement data or the second image according to a comparison result of the signal-to-noise ratio, and
perform the selected correction process to generate the image of the subject.

2. The magnetic resonance imaging apparatus according to claim 1,
wherein the one or more processors calculate a loss of the signal-to-noise ratio of the second image, and select any of a plurality of the correction processes set in advance according to the loss of the signal-to-noise ratio.

3. The magnetic resonance imaging apparatus according to claim 1,
wherein the one or more processors estimate the signal-to-noise ratio of the first image and the signal-to-noise ratio of the second image by using an acceleration rate of the first measurement data and a thinning-out rate of the second measurement data.

4. The magnetic resonance imaging apparatus according to claim 2,
wherein the plurality of correction processes set in advance include processing using a filter and an estimation process of missing data.

5. The magnetic resonance imaging apparatus according to claim 2,
wherein the plurality of correction processes set in advance are processing using a plurality of filters having different intensities or types.

6. The magnetic resonance imaging apparatus according to claim 5,
wherein the filter is a filter having a window function of any of Hanning, Hamming, Gaussian, Kaiser-Blackman, or Fermi, or a window function obtained by combining any two or more of the window functions.

7. The magnetic resonance imaging apparatus according to claim 1,
wherein the one or more processors select the correction process according to the comparison result of the signal-to-noise ratio and a disposition of the movement-affected data on a k-space.

8. The magnetic resonance imaging apparatus according to claim 7,
wherein the one or more processors select a truncation filter process as the correction process in a case in which a proportion of the movement-affected data present in a high-frequency region of the k-space is equal to or greater than a predetermined value.

9. The magnetic resonance imaging apparatus according to claim 7,
wherein the one or more processors select a half estimation process of the measurement data as the correction process in a case in which a proportion of the movement-affected data present in a high-frequency region of the k-space is equal to or greater than a predetermined value.

10. The magnetic resonance imaging apparatus according to claim 1, further comprising:
a UI unit that displays a parameter related to movement correction performed on the measurement data and that accepts setting of the parameter by a user.

11. The magnetic resonance imaging apparatus according to claim 10,
wherein the parameter includes one or more of a type of a movement detection method, an intensity of the movement correction, a type of the correction process, and a threshold value for selecting the correction process, and the UI unit presents at least one of the parameters to the user.

12. An image processing method of processing measurement data consisting of a nuclear magnetic resonance signal collected by a magnetic resonance imaging apparatus to generate an image of a subject, the image processing method comprising:
specifying, as movement-affected data, a nuclear magnetic resonance signal collected in a case in which a movement of the subject is detected;
comparing a signal-to-noise ratio of a first image generated from measurement data before the movement-affected data is removed with a signal-to-noise ratio of a second image generated from measurement data after the movement-affected data is excluded, in the measurement data; and
selecting, from among a plurality of correction processes, a correction process to be applied to at least one of the measurement data after the movement-affected data is excluded or the second image according to a comparison result and performing the selected correction process to generate the image of the subject.
